(19) United States
(12) Patent Application Publication
(10) Pub. No.: US 2012/0152313 A1
(43) Pub. Date: Jun. 21, 2012

(54) VARIOUS TRACKING ALGORITHMS AND APPARATUS FOR A TWO AXIS TRACKER ASSEMBLY IN A CONCENTRATED PHOTOVOLTAIC SYSTEM

(75) Inventors: Brian Hinman, Los Gatos, CA (US); Qiang Xie, San Jose, CA (US)

(73) Assignee: GREENVOLTS, INC, FREMONT, CA (US)

(21) Appl. No.: 13/227,803

(22) Filed: Sep. 8, 2011

Related U.S. Application Data
(60) Provisional application No. 61/424,537, filed on Dec. 17, 2010.
(60) Provisional application No. 61/424,515, filed on Dec. 17, 2010.
(60) Provisional application No. 61/424,518, filed on Dec. 17, 2010.
(60) Provisional application No. 61/424,493, filed on Dec. 17, 2010.

(51) Int. Cl. H01L 31/052

(52) U.S. Cl. 136/246

(57) ABSTRACT

A hybrid solar tracking algorithm is implemented in a two-axis solar tracker mechanism for a concentrated photovoltaic (CPV) system in order to control the movement of the two-axis solar tracker mechanism. The hybrid solar tracking algorithm uses both 1) an Ephemeris calculation and 2) an offset value from a matrix to determine the angular coordinates for the CPV cells contained in the two-axis solar tracker mechanism to be moved to in order to achieve a highest power out of the CPV cells. The matrix populates with data from periodic calibration measurements of actual power being generated by the solar tracker and the tracking algorithm applies Kalman filtering to those measurements over time of the operation of the solar tracking mechanism to create the offset value being applied to the Ephemeris calculation to determine the angular coordinates for the CPV cells.

### RELATED APPLICATIONS

This application is a continuation in part of and claims the benefit of and priority to U.S. Provisional Application titled “Integrated electronics system” filed on Dec. 17, 2010 having application Ser. No. 61/424,537, U.S. Provisional Application titled “Two axis tracker and tracker calibration” filed on Dec. 17, 2010 having application Ser. No. 61/424,515, U.S. provisional application titled “ISIS AND WIFI” filed on Dec. 17, 2010 having application Ser. No. 61/424493, and U.S. Provisional Application titled “Photovoltaic cells and paddles” filed on Dec. 17, 2010 having application Ser. No. 61/424,518.

### NOTICE OF COPYRIGHT

A portion of the disclosure of this patent document contains material that is subject to copyright protection. The copyright owner has no objection to the facsimile reproduction by anyone of the interconnect as it appears in the Patent and Trademark Office Patent file or records, but otherwise reserves all copyright rights whatsoever.

### FIELD

In general, a photovoltaic system having various tracking and mapping algorithms and apparatus for a two-axis tracker assembly is discussed.

### BACKGROUND

Many solar tracking algorithms merely base their tracking of the Sun on trying to track the brightest object in the sky, which can cause the solar tracker assemblies to lose track on cloudy days. Also, some solar tracking programs perform an intensive one-time calibration when the solar tracking mechanism is initially installed, which can lead to future problems during the operation of the solar tracker because the Sun's angle in the sky changes throughout the year as well as mechanical slippage and settling occur throughout the operation of the solar tracker.

### SUMMARY

Various methods and apparatus are described for a photovoltaic system. In an embodiment, a hybrid solar tracking algorithm is implemented in a two-axis solar tracker mechanism for a concentrated photovoltaic (CPV) system in order to control the movement of the two-axis solar tracker mechanism. The hybrid solar tracking algorithm uses both 1) an Ephemeris calculation and 2) an offset value from a matrix to determine the angular coordinates for the CPV cells contained in the two-axis solar tracker mechanism to be moved to in order to achieve a highest power out of the CPV cells. The matrix can be populated with data from periodic calibration measurements of actual power being generated by a power output circuit of the two-axis solar tracker mechanism and applies Kalman filtering to those measurements over time of the operation of the solar tracking mechanism to create an offset value from the matrix applied to results of the Ephemeris calculation to determine the angular coordinates for the CPV cells. A motion control circuit is configured to move the CPV cells to the determined angular coordinates from the offset value being applied to the results of the Ephemeris calculation.

### BRIEF DESCRIPTION OF THE DRAWINGS

The multiple drawings refer to the embodiments of the invention.

FIGS. 1A and 1B illustrate diagrams of an embodiment of a two axis tracking mechanism for a concentrated photovoltaic system having multiple independently movable sets of concentrated photovoltaic solar (CPV) cells.

FIG. 2 illustrates a diagram of an embodiment of a reed switch that is placed on the casing and drive of the slew drive.

FIG. 3 illustrates a high-level flow diagram of an embodiment of a hybrid solar tracking algorithm to determine the angular coordinates for the CPV cells in the paddle assemblies.

FIGS. 4A and 4B illustrate a diagram of an embodiment of a matrix of offset values to account for mechanical errors and other factors in order to combine the offset value with the determined angular coordinates from the solar tracker routine to achieve the maximum power out of a solar array over the entire day and throughout the year.

FIG. 5 shows an example vector coordinate parameter that can be stored in each cell of the tilt and roll grid matrix correlating an offset variance from the ideal angle positioning to achieve maximum power to actual angle positioning to achieve maximum power.

FIG. 6 illustrates a diagram of an embodiment of the motor control circuits, which may include controls for and parameters on the slew drive, tilt linear actuators, and reference reed switches.

While the invention is subject to various modifications and alternative forms, specific embodiments thereof have been shown by way of example in the drawings and will herein be described in detail. The invention should be understood to not be limited to the particular forms disclosed, but on the contrary, the intention is to cover all modifications, equivalents, and alternatives falling within the spirit and scope of the invention.

### DETAILED DISCUSSION

In the following description, numerous specific details are set forth, such as examples of specific voltages, named components, connections, types of circuits, etc., in order to provide a thorough understanding of the present invention. It will be apparent, however, to one skilled in the art that the present invention may be practiced without these specific details. In other instances, well known components or methods have not been described in detail but rather in a block diagram in order to avoid unnecessarily obscuring the present invention. Further specific numeric references such as a first inverter, may be made. However, the specific numeric reference should not be interpreted as a literal sequential order but rather interpreted that the first paddle is different than a second paddle. Thus, the specific details set forth are merely exemplary. The specific details may be varied from and still be contemplated to be within the spirit and scope of the present invention.

In general, various methods and apparatus are discussed. In an embodiment, a hybrid solar tracking algorithm uses an offset value from a matrix applied to results from an Ephemeris calculation to correct the angular coordinates for the CPV cells contained in a two-axis solar tracker mechanism in order to achieve the highest power out of the CPV cells. The matrix can be populated with data from a series of periodic calibration measurements measured from the actual power being generated by a power output circuit of the two-axis solar tracker mechanism and applies a Kalman filtering to those measurements over time of the operation of the solar tracking mechanism. An offset value from the matrix is created from the calibration measurements and Kalman filtering and then applied to results of the Ephemeris calculation in order to determine the angular coordinates for the CPV cells.

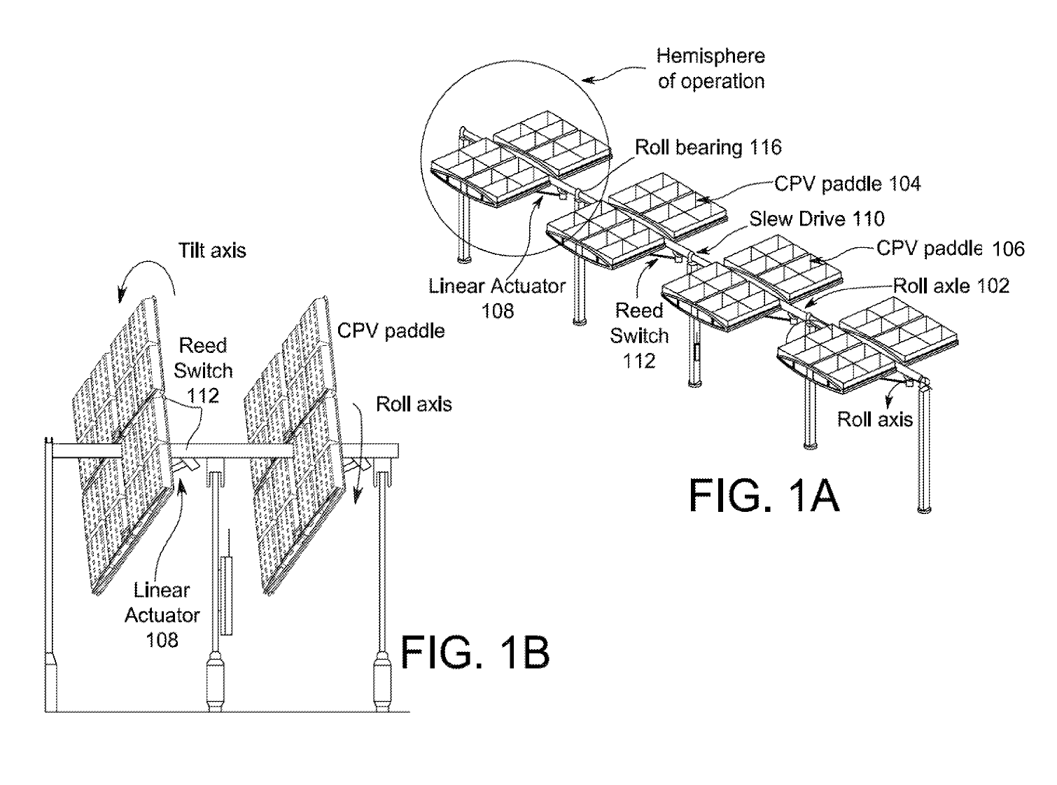

FIGS. 1A and 1B illustrate diagrams of an embodiment of a two axis tracking mechanism for a concentrated photovoltaic system having multiple independently movable sets of concentrated photovoltaic solar (CPV) cells. FIG. 1A shows the paddle assemblies containing the CPV cells, such as four paddle assemblies, at a horizontal position with respect to the common roll axle. FIG. 1B shows the paddle assemblies containing the CPV cells tilted up vertically by the linear actuators with respect to the common roll axle.

A common roll axle 102 is located between 1) stanchions, and 2) multiple CPV paddle assemblies. Each of the multiple paddle assemblies, such as a first paddle assembly 104, contains its own set of the CPV solar cells contained within that CPV paddle assembly that is independently movable from other sets of CPV cells; such as those in the second paddle assembly 106, on that two axis tracking mechanism. Each paddle assembly is independently moveable on its own tilt axis and has its own drive mechanism for that tilt axle. An example number of twenty-four CPV cells exist per module, with eight modules per CPV paddle, two CPV paddles per paddle assembly, a paddle assembly per tilt axis, and four independently-controlled tilt axes per common roll axis.

Each paddle pair assembly has its own tilt axis linear actuator, such as a first linear actuator 108, for its drive mechanism to allow independent movement and optimization of that paddle pair with respect to other paddle pairs in the two-axis tracker mechanism. Each tilt-axle pivots perpendicular to the common roll axle 102. The common roll axle 102 includes two or more sections of roll beams that couple to the slew drive motor 110 and then the roll beams couple with roll bearing assembly with pin holes for maintaining the roll axis alignment of the solar two-axis tracker mechanism at the other ends, to form a common roll axle 102. The slew drive motor 110 and roll bearing assemblies are supported directly on the stanchions. A motor control board in the integrated electronics housing on the solar tracker causes the linear tilt actuators and slew drive motor 110 to combine to move each paddle assembly and its CPV cells within to any angle in that paddle assembly's hemisphere of operation. Each paddle assembly rotates on its own tilt axis and the paddle assemblies all rotate together in the roll axis on the common roll axle 102.

The tracker circuitry uses primarily the Sun's angle in the sky relative to that solar array to move the angle of the paddles to the proper position to achieve maximum irradiance. A hybrid algorithm determines the known location of the Sun relative to that solar array via parameters including time of the day, geographical location, and time of the year supplied from a local GPS unit on the tracker, or other similar source. The two-axis tracker tracks the Sun based on the continuous latitude and longitude feed from the GPS and a continuous time and date feed. The hybrid algorithm will also make fine tune adjustments of the positioning of the modules in the paddles by periodically analyzing the power (I-V) curves coming out of the electrical power output circuits to maximize the power coming out that solar tracker.

The hybrid solar tracking algorithm supplies guidance to the motor control board for the slew drive and tilt actuators to control the movement of the two-axis solar tracker mechanism. The hybrid solar tracking algorithm uses both 1) an Ephemeris calculation and 2) an offset value from a matrix to determine the angular coordinates for the CPV cells contained in the two-axis solar tracker mechanism to be moved to in order to achieve a highest power out of the CPV cells. The matrix can be populated with data from periodic calibration measurements of actual power being generated by a power output circuit of the two-axis solar tracker mechanism and applies Kalman filtering to those measurements over time of the operation of the solar tracking mechanism to create an offset value from the matrix applied to results of the Ephemeris calculation to determine the angular coordinates for the CPV cells. The motion control circuit is configured to move the CPV cells to the determined angular coordinates resulting from the offset value being applied to the results of the Ephemeris calculation.

The two-axis tracker includes a precision linear actuator for each of the paddle pairs in the four paddle pairs joined on the shared stanchions as well as the slew drive connect to the common roll axle 102. A set of magnetic reed sensors can be used to determine reference position for tilt linear actuators to control the tilt axis as well as the slew motor to control the roll axis on the common roll axle 102. Each tilt linear actuator may have its own magnetic reed switch sensor, such as a first magnetic reed sensor 112. For the tilt reference reed sensor, on for example the south side of each paddle pair and on the east side of the roll beam, a tilt sensor mounts and tilt sensor switch is installed in the holes provided on the roll beam past the end of the paddle. Also, on the paddle assembly, the magnet mount and magnet are screwed in.

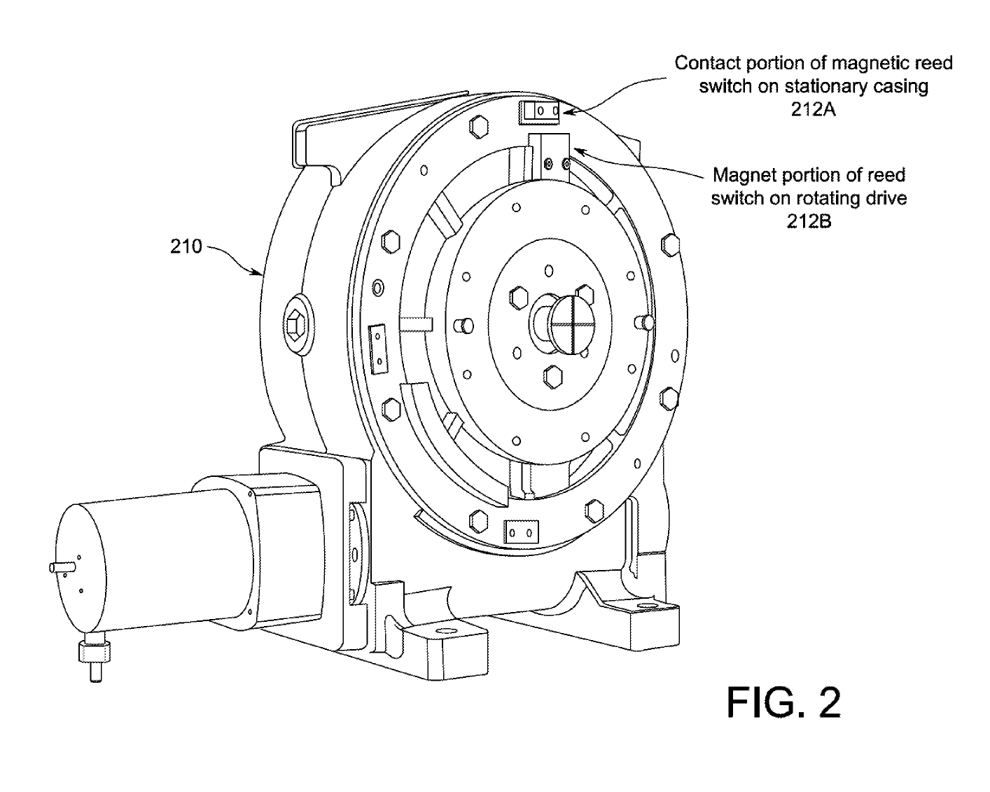

FIG. 2 illustrates a diagram of an embodiment of a reed switch that is placed on the casing and drive of the slew drive. The reed switch contact portion 212A is installed at a known fixed location on the stationary casing of the slew drive 210. The magnetic portion 212B of the reed switch 210 is installed at a known fixed location on the rotating portion that couples to the common roll axle. Thus, a set of, for example, five magnetic reed switches are used to provide reference positions of the paddles during operation. This set of magnetic reed sensors, one at each measured axis, is used to determine 1) a reference position for the tilt linear actuators to control the tilt axis of the CPV cells as well as 2) a reference position for the slew drive motor 210 to control the roll axis of the CPV cells. A total of, for example, four magnetic reed switches are used on the bottoms of the four paddle pairs indicate a tilt axis angle of 0, 0 for the linear actuators, and one magnetic reed switch is used on the slew drive motor to indicate a roll axis angle of 0, 0 for the slew drive. These magnetic reed sensors are located and configured to allow a degree of rotation on the roll axis of the solar tracker to be accurately correlatable to a number of rotations of the slew drive motor 210. Similarly, the magnetic reed sensors for the tilt axis are located and configured to allow a position along each linear actuator to be accurately correlatable to a degree of rotation on the tilt axis of the solar tracker. Thus, the magnetic reed switch portion of a given magnetic reed sensor for the roll axis can be located on a stationary surface, such as the outer casing of slew drive by the common roll axle coupled to the slew drive, OR on a rotating surface such as the roll axle. The magnetic portion of a given magnetic reed sensor can be affixed to a rotating component of the two axis tracker mechanism, such as the drive portion of the slew drive coupling to the common roll axle or the paddle containing the CPV cells. Once the magnetic reed sensors create the reference position for the axes, then the degree of rotation of the CPV cells in the paddles on the roll axis is correlatable to a number of rotations of the slew drive motor 210, and the degree of rotation of the CPV cells in each of paddle assemblies on the tilt axis is also correlatable to an amount of movement in that paddle assemblies corresponding linear actuator.

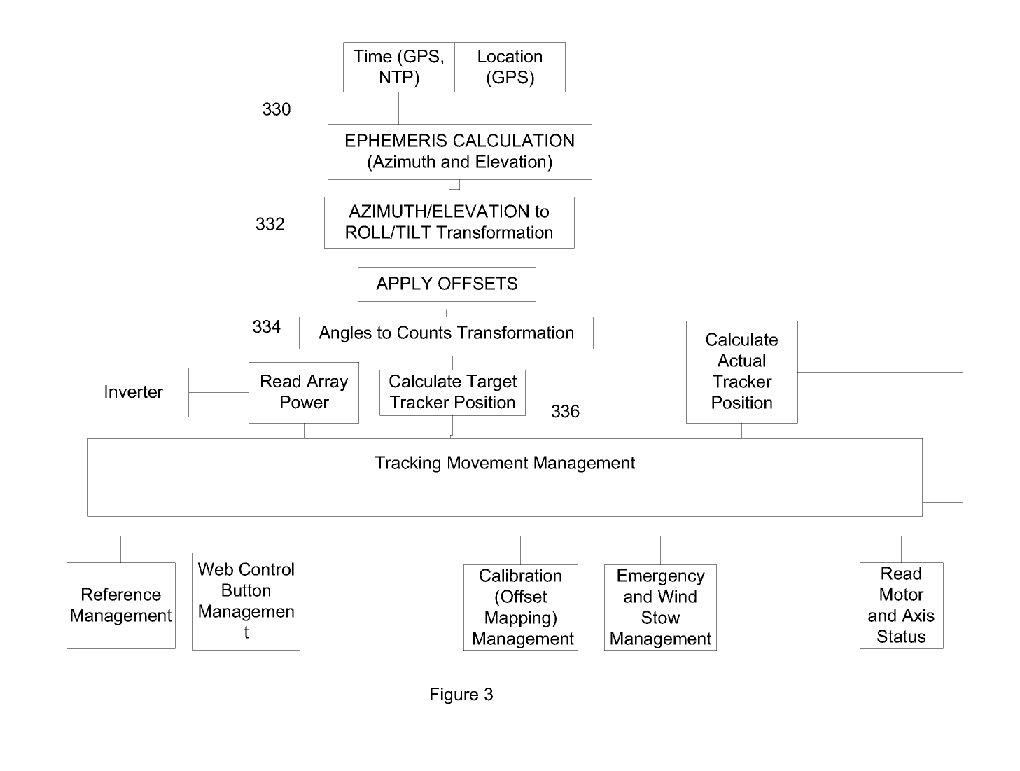

FIG. 3 illustrates a high-level flow diagram of an embodiment of a hybrid solar tracking algorithm to determine the angular coordinates for the CPV cells in the paddle assemblies. One or more of the below steps may generally performed out of sequential order and still accomplish the same result. Further, more detailed discussions of each step also occur throughout this document.

In step 330, the hybrid solar tracking algorithm uses the calculated azimuth and elevation of the Sun from the Ephemeris calculation. The Ephemeris calculation receives the known GPS coordinates of the solar tracker, the current time of day, and date, to determine the ideal proper angle of the CPV cells relative to a current position of the Sun for the highest power. The highly accurate solar tracking routine determines the known location of the Sun in the sky in relation to CPV cells on the two-axis tracker mechanism and receives time, date, and coordinate parameters from the electronic circuits housed on the two-axis tracker mechanism itself. The electronic circuits housed on the two-axis tracker mechanism supply the parameters of at least the current date, hour, and minute as well as latitude and longitude of the two-axis tracker mechanism. Each solar tracker mechanism with its multiple paddle pair assemblies has its own GPS device potentially within or on a housing of the electronic circuits housed on the two-axis tracker mechanism. Potentially hundreds or thousands of solar tracker mechanisms exist in a solar generation facility. The highly accurate solar tracking routine uses the Ephemeris calculation with the local GPS position data of the solar tracker mechanism and the current time parameters to determine the angular coordinates that CPV cells contained in the solar tracker mechanism should be ideally positioned relative to the current position of the Sun.

In step 332, the hybrid solar tracking algorithm applies a transformation operation to convert an azimuth and elevation parameter from the Ephemeris calculation to tilt and roll angle parameters for the CPV cells in the paddle assemblies. The results from ephemeris calculation are azimuth (AZ) and elevation (EL) angles. Note, some ephemeris calculations use zenith angle (90 degree—EL) instead of elevation angle. Either way, the coordinate transformation operation converts the Sun's position in the sky relative to the tracker into roll (RL) and tilt (TL) angles instead of azimuth (AZ) and elevation (EL) angles.

In step 332, the hybrid solar tracking algorithm also applies an offset value from the matrix to the results of the Ephemeris calculation. The offset value is from the matrix to correct the angular coordinates for CPV cells contained in the two-axis solar tracker mechanism from those generated by the Ephemeris calculation alone in order to achieve the highest power out of the CPV cells. The hybrid solar tracking algorithm periodically makes the calibration measurement on actual power over the operation of the solar tracker at two or more calibration points/(slightly different angles of the CPV cells relative to the Sun) in a search algorithm to generate the offset value to be applied to the results of the Ephemeris calculation. The matrix is populated with data from these periodic calibration measurements of actual power being generated by a power output circuit of the two-axis solar tracker mechanism and applies the Kalman filtering to those measurements over time of the operation of the solar tracking mechanism to create an offset value from the matrix applied to results of the Ephemeris calculation to determine the angular coordinates for the CPV cells.

In step 334, a second transformation operation occurs to correlate tilt and roll axes angle parameters for the CPV cells in the paddle assemblies into the amount of movement required by the slew drive and linear tilt actuators. As discussed, once the magnetic reed sensors create the reference position for the axes, then the degree of rotation of the CPV cells in the paddles on the roll axis is correlatable to a number of rotations of the slew drive motor, and the degree of rotation of the CPV cells in each of paddle assemblies on the tilt axis is also correlatable to an amount of movement in that paddle assemblies corresponding linear actuator. As discussed later, a sensor position offset value parameter is applied to current roll and tilt axes angle parameters. The sensor position offset value parameter is created and stored in firmware to indicate a deviation from a physically measured level condition in that axis for the CPV cells, and what reading the magnetic reed sensors indicated at that time when the physically measured level condition was taken. The hybrid algorithm uses these parameters to calculate then a target position that the CPV cells contained in the paddle assemblies should be moved to.

In an embodiment, the tilt angle to counts conversion factors in that the two-axis tracker uses a linear actuator to drive rotational movement in tilt axis. When linear actuator extends and retracts, the paddle changes tilt angles. Since the position feedback reed switch for tilt axis is mounted on the jackscrew shaft of the actuator, the reading of its counts can be directly related to the linear distance change of the actuator. A trigonometric calculation then converts distance change to tilt angle change.

In step 336, the motor control board receives the calculated target position that the CPV cells should be moved to as well as the current positions of the motors. The motor control board then moves the paddle assemblies containing the CPV cells to the targeted position.

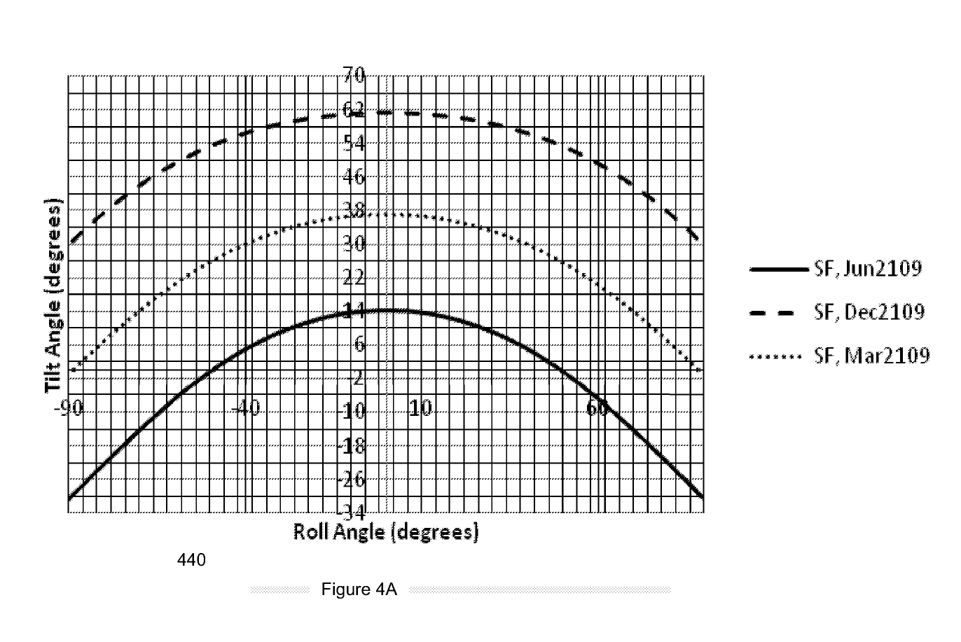

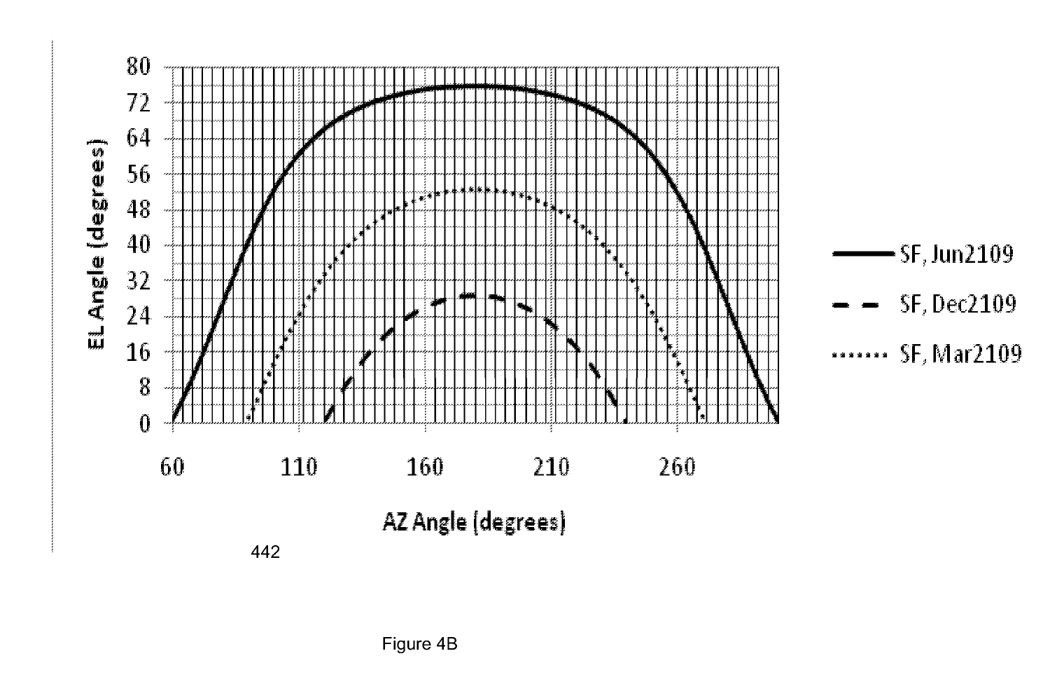

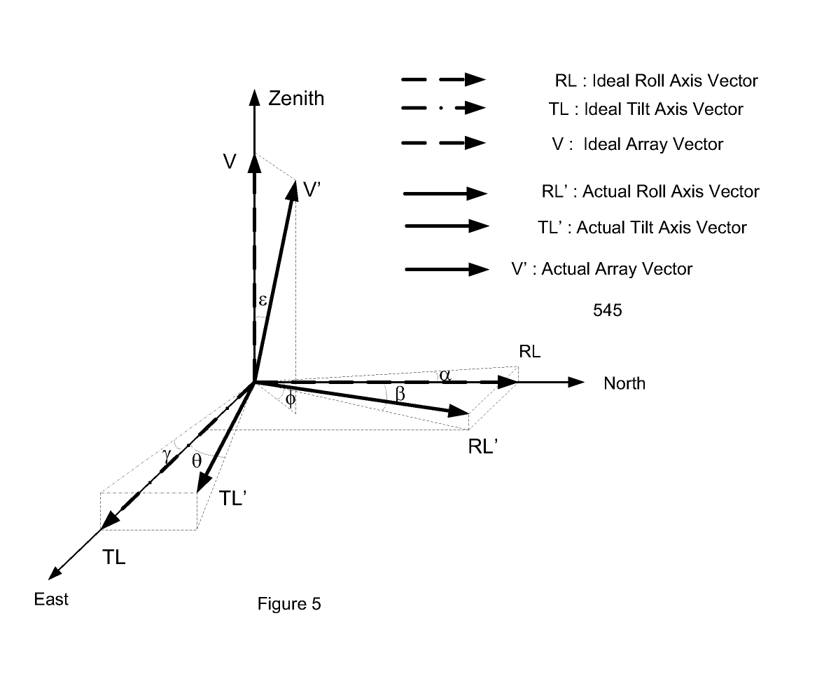

FIGS. 4A and 4B illustrate a diagram of an embodiment of a matrix of offset values to account for mechanical errors and other factors in order to combine the offset value with the determined angular coordinates from the solar tracker routine to achieve the maximum power out of a solar array over the entire day and throughout the year. FIG. 4A shows a rectangular grid matrix 440 for tilt and roll axes angles comprised of many cells and supper imposed on the matrix is the solar path of the Sun for the example days in the months of June, December and March. FIG. 4B shows a rectangular grid matrix 442 for azimuth and elevation axes angles comprised of many cells and supper imposed on the matrix is the solar path of the Sun for the example days in the months of June, December and March. One or both of the example grid matrixes could be used to store and produce the offset value applied to the Ephemeris calculation. FIG. 5 shows an example vector coordinate parameter 545 that can be stored in each cell of the tilt and roll grid matrix correlating an offset variance from the ideal angle positioning to achieve maximum power to actual angle positioning to achieve maximum power. Referring to FIGS. 4A and 4B, the offset table grid 440, 442 populates with offset values when the periodic calibrations occur on that cell in the matrix that day. Most of the cells eventually are populated throughout the year. Each cell in the matrix corresponds to a specific period of time in the calendar year. The hybrid solar tracking algorithm uses these calibration measurements and this Kalman filtering process to populate the cells of the offset matrix with the offset values.

Each cell contains the offset vectors for each of the axis of the solar tracker. For example, 5 offset vectors (1 roll, 4 tilt vectors) and 5 corresponding events counts such as cumulative events (CE) can be populated, updated and stored in that cell. The CE parameter tells how many times a cell in the offset matrix has been updated. It will range from 0 to 9. FIG. 5 shows the ideal roll axis vector coordinate parameter and the deviation from that vector to the actual roll axis vector found to achieve maximum power, and the corresponding offset can be stored in each cell of the tilt and roll grid matrix. Likewise, FIG. 5 shows the ideal tilt axis vector coordinate parameter for a given linear actuator and the deviation from that vector to the actual tilt axis vector found to achieve maximum power. Likewise, FIG. 5 shows the same for the array vector.

The cells of the offset matrix can be initially blank and the hybrid algorithm may use a counter to keep track of each time a calibration procedure occurs for a given cell to determine the actual power coming out of the solar tracker and then generate an offset value for that the cell. Each time the calibration procedure occurs to generate data for the offset values for that cell and the counter increases its value, then the confidence factor goes up that the correct offset value for this particular two axis solar tracker mechanism as constructed and operating is being created and applied to the results of the Ephemeris calculation, which the combination aligns the CPV cells of this tracker mechanism at the proper angle to achieve the highest power from the inverter circuits of the tracker mechanism on each day and each hour of operation of the solar tracker throughout the entire year.

The algorithm determines and fills out the offset values over time in the cells of the offset table matrix. As shown in FIG. 4A, the solar paths in Tilt/Roll domain are all in same shapes with the same roll angle spanning from −90 degrees to +90 degrees. Each day the solar path is just a slight parallel move in tilt axis. So it is very likely that there will be only very small and possible linear changes in offset value from day to day.

Referring back to FIG. 3, the hybrid tracking algorithm controls paddle position in order to extract maximum power from the CPV array. The hybrid tracking algorithm has an open and closed loop portion.

Open Loop Portion of the Hybrid Algorithm

The tracker circuitry uses primarily the Sun's angle in the sky relative to that solar array to move the angle of the paddles to the proper position to achieve maximum irradiance. The hybrid algorithm determines the known location of the Sun relative to that solar array via parameters including time of the day, geographical location, and time of the year supplied from a local GPS unit on the tracker, or other similar source. Thus, the solar tracking routine, which includes the Ephemeris calculation, determines the position of Sun in the sky relative to that tracker assembly via receiving time of day, date, and global positioning system coordinates of tracker. The positioning of the paddles is continuously updated throughout the day. Thus, this portion of the hybrid solar tracking algorithm achieves nearly maximum power output, such as at least 95% of theoretical maximum power out of the solar array, by itself. The solar tracking routine is fed time, date, latitude and longitude on a continuous basis during the day, which allows the hybrid tracker algorithm to track the position of the Sun extremely accurately throughout the day because each minute of the day the tracker knows exactly where the Sun is located in the sky relative to that tracker. A passing cloud or momentary brighter object will not cause the tracker to completely lose its lock on where and what angle the paddles should be pointing.

Ephemeris Calculations

Ephemeris functions calculate solar position (azimuth and elevation angles) in the sky for any given time and location. There are different versions of ephemeris calculations ranging from very complicated and accurate to very simple but less accurate. One simple version of ephemeris is based on the HM Nautical Almanac Office (NAO) Technical Note No. 46 (1978), Yallop B. D.—“Formulae for computing astronomical data with hand-held calculators”. It is a simple and quick implementation of ephemeris with good enough accuracy (<0.1 degrees for elevation angle above 6 degrees). A much more complicated ephemeris algorithm is from National Renewable Energy Laboratory (NREL), Ibrahim Reda and Afshin Andreas, “Solar Position Algorithm for Solar Radiation Applications”. It gives out an algorithm to be within ±0.0003 degrees of uncertainty for azimuth and elevation angles from year −2000 to 6000. Source code of the algorithm is also available on line from NREL web site. In a simple form, the ephemeris can be summarized as:

AZ, EL=f(t, Longitude, Latitude)

Where AZ is: azimuth angle; EL is: elevation angle; and t is: time (usually in UTC).

The two-axis tracker tracks the Sun based on continuous latitude and longitude feed from the GPS and a continuous time and date feed plugged in as parameters to an Ephemeris function.

Closed Loop Portion of the Hybrid Algorithm

As discussed, the two axis tracker tracks the Sun based on continuous latitude and longitude feed from the GPS and a continuous time and date feed, and the hybrid algorithm can also make fine tune adjustments of the positioning of the modules in the paddles by periodically analyzing the actual power, such as (I-V) curves, coming out of the inverter AC power output circuit to maximize the power coming out that solar tracker mechanism. Thus, the measured actual power output from the AC generation inverter circuits may taken off the (I-V) curves and taken with a set of two or more calibration points. The results from the calibration measurements are recorded into a cell of the offset matrix corresponding to that time and day of the year when the actual power output was measured, and the offset value stored in the cell is indicative of changes needed to adjust the ideal angular positioning of the CPV cells resulting from the Ephemeris calculation into the actual angular position needed for maximum power.

In an embodiment, the calibration measurement uses the measured electrical power out of the inverter circuits of the solar tracker and then factors in a measured direct normal incidence of solar radiation at that two-axis tracker mechanism at the time when the electrical power measurement is made. The direct normal incidence of solar radiation can be factored in by, for example, dividing the actual measured electrical power by the direct normal incidence at the time the measurement is made, to determine the highest power out of the solar tracker. Note, typically, a set of five electrical power measurements at the slightly different angles will be made in a span of 2.5 minutes and the momentary solar radiation present can be reflected in DNI measurements. Factoring in DNI at the time the power measurement is made for that particular calibration point can minimize affect of the changing rate of radiation supplied by the Sun at different points in the day as well as during the year.

The offset factor takes into account to factor in mechanical slippage and other factors to correspond the ideal position of the CPV cells to an actual position of the CPV that maximizes power. The hybrid solar tracking algorithm periodically makes the calibration measurement of actual power over the operation of the solar tracker at two or more calibration points/(slightly different angles of the CPV cells relative to the Sun) in a search algorithm to generate this offset value to be stored in the cells of the matrix. The calibration measurement of actual electrical power being generated from the inverter circuits of the solar tracker mechanism captures two or more data points where the actual relationship of the angle of the CPV cells in the solar tracking mechanism relative to the current position of the Sun is varied from the ideal angle. This offset value stored in the cell indicates the changes needed to the ideal angular positioning of the CPV cells resulting from the Ephemeris calculation. Over a year's time, the hybrid algorithm then populates each cell of the offset matrix with this data. Over the operation lifetime of the two-axis tracker, the hybrid algorithm uses Kalman filtering on the measurements observed and recorded over the time while the tracker is in service to generate updated versions of the offset value to be applied to the results of the Ephemeris calculation. Thus, the Kalman filtering over time of the operation of the solar tracking mechanism generates an updated version of the offset value for each of the cells of the offset matrix to take into account both mechanical slippage and alignment issues over time as well as tracker mechanism settling into the ground issues over time.

Accordingly, the hybrid algorithm not only procedurally performs an initial calibration which provides data for that cell of the offset matrix, but then performs subsequent calibrations for that same cell periodically after that. In addition, the hybrid two-axis solar tracking algorithm on the subsequent calibrations for that same cell both 1) decreases over time the frequency of the updates of data samples representative of the random variations for mechanical and other in accuracies and 2) decreases the offset range of search point positions that the solar tracker moves the CPV cells to when conducting the calibration process that measures actual power being generated by the power output circuit. The offset range of search point positions repositions the CPV cells during calibration at slightly different angles and at each angle, then an inverter power measurement occurs.

The offset values for all of the cells making at least a year's worth of entries in the matrix is created and maintained via the calibration procedure during the operation of the solar tracker mechanism. Each time a calibration occurs to determine the offset value for that particular cell then the confidence level in the offset value grows. The hybrid algorithm is configured to both 1) decrease the frequency of the calibration procedure occurring for that cell as well as 2) narrow down the range of search angles for the CPV cells deviating from a suggested starting angle used in the search algorithm to determine a highest power out of the two axis solar tracker. Thus, the hybrid solar tracking algorithm takes into account how many times actual calibration procedures have occurred for this cell of the matrix to determine the confidence level in that offset value and consequently 1) how frequent calibrations will occur and 2) the size of the range of deviation of search points from a starting angle that occurs in the calibration process for this cell. Thus, the hybrid algorithm controls both 1) a step size/range of calibration positions used by a search algorithm in determining actual measured power out of the tracker mechanism as well as 2) a frequency of performing calibrations on a given cell in the offset matrix based on a confidence level in the offset value applied to the results of the Ephemeris calculation.

Some Additional Points

Tilt Actuator and Slew Drive Reference Position Sensors

The paddle pairs on the tracker assembly are first physically aligned in the three dimensions with each other. When the four paddles have been physically checked to ensure they are all level on the horizontal plane along the center line of the tracker and horizontal plane perpendicular to the center line of the tracker, then the rotating magnet on the drive will be aligned with the stationary magnetic contact on the drive casing. This will be the 0 degrees coordinate for the roll axis. Any small discrepancy between the measured physical level alignment and when the reed switch indicates 0 degree will be stored as an offset value in a memory to reset 0 degrees and create a virtual 0 degree coordinate. A similar set up exits with the linear actuator and the tilt axis. For example, the electrical contact portion of magnetic reed switch is placed on the roll beam. The magnet portion of reed switch is positioned on the rotating paddles, for example, on a corner of the paddle. Any small discrepancy between the measured physical level alignment of the tilt axis for the paddle and when the reed switch indicates 0 degree by the magnet aligning with the contact will be stored as an offset value in a memory to reset 0 degrees and create a virtual 0 degree coordinate.

Thus, these physically level paddles in all three dimensions are used as a base to establish a virtual level position of 0, 0 degrees coordinates in the drive motor for the roll axis and a virtual level position of 0, 0 degrees coordinates in the linear actuators for the tilt axis. Any difference between the reed switch indication of being level and the physically measured position of the paddles when the digital level indicates they are level is stored as an offset for that paddle pair to create the virtual level.

The degree of rotation on the roll axis is then correlatable to a number of rotations of the drive to the degree of rotation of the paddles. For example, each time the magnet pass the stationary contact that may equal one rotation of the drive and 20,000 of those rotations may equal the paddles rotating +and −180 degrees of in the roll axis. On the linear actuator, the amount of movement of the linear actuator is also correlatable to the degree of rotation on the tilt axis of the paddles.

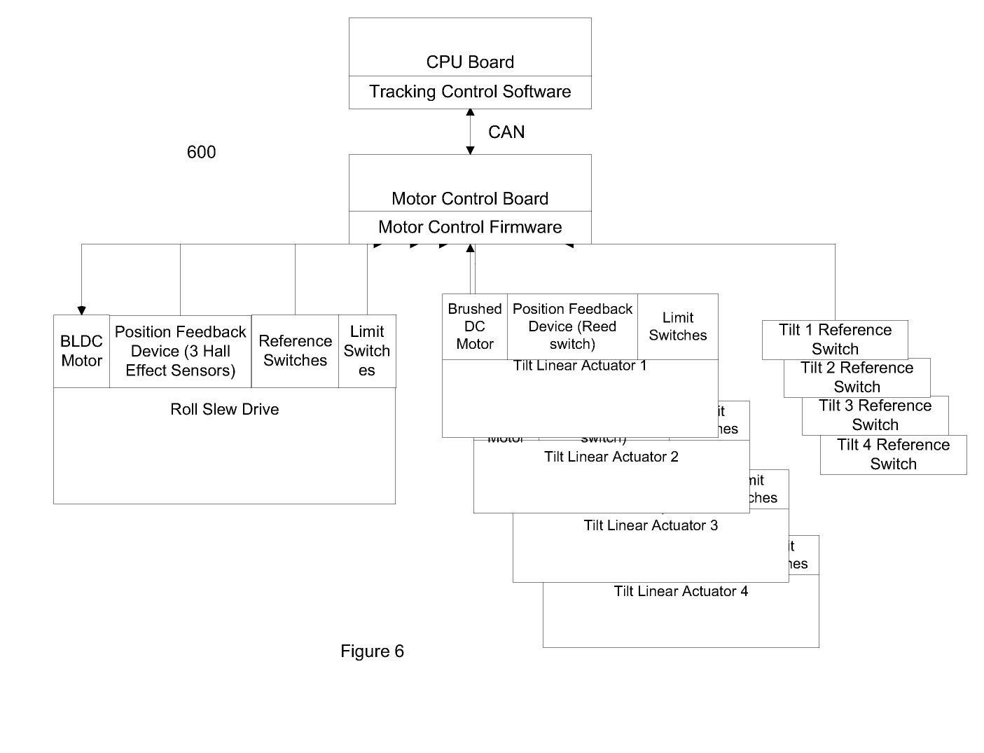

FIG. 6 illustrates a diagram of an embodiment of the motor control circuits 600, which may include controls for and parameters on the slew drive, tilt linear actuators, and reference reed switches. Referring to FIG. 6, in addition, the slew drive of the two-axis tracker may have a bodine motor, flange Mounts, a hard stop to prevent the motor from ever rotating backwards from the direction it is intending to drive, reed sensor and limit switch mounts.

Also, an integrated electronics housing with the inverter electronic circuits also contains the tracker motion control circuits for the four tilt motors for the linear actuators and the one slew drive roll motor for a combination of continuous and discrete motion to achieve high-accuracy. The housing may also contain the local code employed for the Sun tacking algorithms for each paddle assembly.

The elevation and angle of the Sun changes throughout the year. The offset mapping process finds and continuously updates the offset vectors for each table grid on the solar path. A year is made up of four seasons, and the angle of the position of the Sun varies significantly over those seasons. As it takes an entire year to get calibration data over all of the cells in the matrix some extrapolating and interpolating can be used to fill out the matrix for the offset data. Adjacent cells may use offset values from each other as an initial starting point.

Note, if the solar array is installed around the autumnal equinox, the path of the Sun is changing rapidly each day. Without regularly updated calibration data for the lower elevations in the sky, the tracker could become very far off target if the algorithm waited for weeks or months until the next calibration. As the angles of the paddles change over the seasons to match the angle of the Sun in the sky, new data is plotted via the sampling in the offset matrix to determine the correct virtual offset to make up for the small mechanical misalignments in the complete hemisphere of operation.

At installation time, the matrix is configured with the a choice of starting with all values set to zero/just left blank, or uploading an offset matrix from the back-end management system. The offset value of a particular cell can be communicated to all adjacent cells in the matrix to assist in determining a starting point to for the predicted offset value of the adjacent cells.

Note, keeping track of the number of times a calibration has occurred and the corresponding data serves two important functions: (1.) allows the hybrid algorithm to average over scans since an individual scan may have error due to environmental conditions such as wind, and (2.) allows the hybrid algorithm to adapt the scan range in accordance with the known accuracy of the offset parameters.

The offset table based on tracking error data from samples taken over time can be created and maintained by its own offset matrix algorithm, which forms a part of the hybrid solar tracking algorithm.

Thus, the Kalman filtering for the offset matrix uses measurements that are observed over time that contain random variations for mechanical in accuracies etc. and other inaccuracies, and after the application of the offset then produces values that tend to be closer to the true values of the measurements and their associated calculated values. The samples for this algorithm are periodically taken, such as quarterly, daily, hourly, even every minute to find the offset amount needed to achieve the highest power out. In addition, the hybrid two-axis solar tracking algorithm decreases over time the frequency of the updates of the samples for the random variations for mechanical and other in accuracies and the range of those samples. However, persistent checking of actual power out to predicted power out will still occur to update the matrix.

Calibrations

The hybrid solar tracking algorithm uses a calibration procedure that takes multiple points of data for each paddle in the hemisphere of operation to determine an appropriate offset for positioning the paddles to achieve a highest output power of that solar array. The periodic calibrations may occur at a constrained amount of calibration points, for example, the predicted offset value and two deviation points on each side of predicted offset value.

An Example Closed-Loop Portion of the Offset Algorithm May be as Follows.

Mapping of the offset value into the cells of the matrix comes from the periodic calibration scans for each axis. There may be an example number of four tilt linear actuator drives and one slew roll drive and each such axis will have parameters. Each will have a pair of stored offset parameters, cumulative ticks (CT) and cumulative events (CE). As discussed, the CE parameter tells how many times a cell in the offset matrix has been updated. It will range from 0 to 9. Most of the time, CE will be the same for all drives within a given cell. However, there are cases when a subset of the cells has been updated and an exceptional condition occurs (e.g. power outage, wind-safe command issued). Such an exceptional condition will cause the CE parameter to become offset within the dataset. The example ten parameters stored within the depth of the offset matrix are thus:
CTRoll, CERoll
CTTilt1, CETilt1
CTTilt2, CETilt2
CTTilt3, CETilt3
CTTilt4, CETilt4
CTTilt5, CETilt5

Where CT tilt is (cumulative encoder ticks for the tilt angle) that is correlatable to the amount of movement of the linear actuator; and

CT roll is (cumulative encoder ticks for the roll angle) that is correlatable to the amount of movement of the slew drive.

Normal Ephemeris Update

The algorithm will initially perform the Ephemeris calculation every X amount of time and execute updates to the tilt and roll drives as necessary. The X amount of time, time frame may be broken into portions of the day. A new position can be determined as follows:

(1.) Run ephemeral calculation with the time and position supplied from the local GPS unit that then gives azimuth (AZ) and elevation (EL);

(2.) AZ′=AZ−AO (compute adjusted AZ′ knowing azimuth offset value from matrix);

(3.) Rotate AZ′ and EL into tilt angle (TL) and roll angle (RL). The azimuth and elevation angles of the Sun relative to the location of that particular solar array are transformed into tilt and roll angles of the paddles; and

(4.) Convert TL and RL into absolute encoder counts tilt encoder counts (TEC) and roll encoder counts (REC). RL to REC can be performed by multiplication. TL to TEC requires an algebraic computation or table look-up. Thus, the amount of movement of the linear actuators and slew drive from the tilt and roll angles are required inputs. The example computation flow is:

REC=INT (k*RL)+RO+INT (CTRoll (INT (AZ/IO), INT(EL/IO>>/CERoll (INT (AZ/I0), INT (EL/I0>>)

TECi=f (TL)+TOi+INT (CTTilti (INT(AZ/IO), INT (EL/IO>>/CETilti (INT(AZ/I0), INT(EL/I0>>)

A calibration scan may include five search algorithm calibration points that record the inverter electrical power measurement at that search algorithm calibration point. The scan range of the calibration points can be adaptively adjusted such as (−range, −0.5 *range, 0, 0.5 *range, range). Scan range of the calibration points will be decreased potentially each time a scan is happening on the same cell grid. Note, 0.5 is merely an example number chosen and others are possible. Also, each scan for calibration points can be conducted based on the previous scan offset values as well as what scan offset values have been determined for adjacent cells in the matrix grid.

The offset matrix initially searches for angles to achieve max power over a broader range, and gradually gathers more and more calibration data, to allow use of progressively tighter search regions for angles to achieve max power. For example:

If MIN (CERoll, CETilti)=0 then Scan Range=−0.5 degrees to +0.5 degrees;

If MIN (CERoll, CETilti)=1 then Scan Range=−0.4 degrees to +0.4 degrees;

If MIN (CERoll, CETilti)=2 then Scan Range=−0.3 degrees to +0.3 degrees; and

If MIN (CERoll, CETilti)>2 then Scan Range=−0.2 degrees to +0.2 degrees.

As discussed, the closed loop portion of the hybrid algorithm will do both reduce the scan search range and also perform the frequency of scans less often as the cell's updated offset value becomes refined. For example, with 10 degree bins and scans each 10 minutes, the algorithm gets four updates per cell per day. The offset algorithm backs off to every 20 minutes after two updates, and then to every 40 minutes after four updates. As soon as the algorithm encounters an empty cell, though, it is back to the maximum scan range (+/−0.5 degrees) and every 10 minutes. Once the amount of offset due to mechanical and other factors is determined from the ideal angular coordinates has been determine for the first couple of searches, then the search range can be decreased by setting the determined offset as the center of the search range and decrease the range of the search to, for example, +/−0.2 degrees to even more slightly improve the power out of the solar array at that time and date.

Also of note is that operationally, optimally tracking the Sun with four independently moveable paddle pair assemblies on a solar array is easier and more accurate across the four paddle pairs than with a single large array occupying approximately the same amount of area as the four arrays.

Although the foregoing embodiments have been described in some detail for purposes of clarity of understanding, the invention is not limited to the details provided. The Solar array may be organized into one or more paddle pairs. The matrix may be implemented but also a similar technique could be used in a mathematical polynomial expression. Functionality of circuit blocks may be implemented in hardware logic, active components including capacitors and inductors, resistors, and other similar electrical components. Functionality can be configured with hardware logic, software coding, and any combination of the two. Any software coded algorithms or functions will be stored on a corresponding machine-readable medium in an executable format. The two axis tracker assembly may be a multiple axis tracker assembly in three or more axes. There are many alternative ways of implementing the invention. The disclosed embodiments are illustrative and not restrictive.

We claim:

1. A hybrid solar tracking algorithm for a two-axis tracker mechanism for a concentrated photovoltaic system to control a movement of a two-axis solar tracker mechanism, comprising:
where the hybrid solar tracking algorithm uses both 1) an Ephemeris calculation to supply the position of the Sun and 2) an offset value applied to results of the Ephemeris calculation to determine angular coordinates that the CPV cells contained in the two-axis solar tracker mechanism should be positioned at, in actuality, relative to a current position of the Sun to achieve a highest power output from a solar array containing the CPV cells, and
where the offset value is derived from a periodic calibration measurement of actual power being generated from a power output circuit coupled to the CPV cells in the solar array, which the data of the periodic calibration measurement is supplied to an offset matrix that uses Kalman filtering to evaluate those measurements over time of the operation of the two-axis solar tracking mechanism to create the offset value to be applied to the results of the Ephemeris calculation in order to determine the angular coordinates that the CPV cells contained in the two-axis solar tracker mechanism should be at in actuality to achieve the highest power output from the solar array, and where a motion control circuit is configured to move the CPV cells to the determined angular coordinates resulting from the offset value being applied to the results of the Ephemeris calculation.

2. The hybrid solar tracking algorithm for a two-axis tracker mechanism of claim 1, where the hybrid solar tracking algorithm uses the calculated azimuth and elevation of the Sun from the Ephemeris calculation, and where the Ephemeris calculation receives the known GPS coordinates of the solar tracker, the current time of day, and date, to determine the ideal proper angle of the CPV cells relative to a current position of the Sun for the highest power, and where the hybrid solar tracking algorithm periodically makes the calibration measurement on actual power over the operation of the solar tracker at two or more calibration points in a search algorithm to generate the offset value to be applied to the results of the Ephemeris calculation, where the solar tracker mechanism has its own GPS device.

3. The hybrid solar tracking algorithm for a two-axis tracker mechanism of claim 1, where a calibration measurement of actual electrical power being generated from the power output circuits of the solar tracker mechanism captures two or more data points where the actual relationship of the angle of the CPV cells in the solar tracking mechanism relative to the current position of the Sun is varied from the ideal angle, and the hybrid algorithm then populates a cell of the offset matrix with this data and uses Kalman filtering observed and recorded over time while the tracker is in service to generate an updated version of the offset value to be applied to the results of the Ephemeris calculation, and the power output circuit is an AC voltage inverter circuit of the two-axis tracker mechanism.

4. The hybrid solar tracking algorithm for a two-axis tracker mechanism of claim 1, where the Kalman filtering over time of the operation of the two axis solar tracking mechanism generates an updated version of the offset value for each of the cells of the offset matrix, where this hybrid solar tracking algorithm takes into account both mechanical slippage and alignment issues over time as well as tracker mechanism settling into the ground issues over time, and where each cell in the matrix corresponds to a specific period of time in the calendar year.

5. The hybrid solar tracking algorithm for a two-axis tracker mechanism of claim 1, where the hybrid solar tracking algorithm determines and records offset values over time in cells of an offset table matrix to compensate for mechanical errors, and the offset values are derived from calibration measurements of electrical power from the inverter circuits of the two-axis tracker mechanism, which are the power output circuit of the two-axis tracker mechanism.

6. The hybrid solar tracking algorithm for a two-axis tracker mechanism of claim 1, where the cells of the offset matrix are initially blank and the hybrid algorithm may use a counter to keep track of each time a calibration procedure occurs for a given cell to determine the actual power coming out of the solar tracker and then generate an offset value for that the cell, and
where each time the calibration procedure occurs to generate data for the offset values for that cell and the counter increases its value, then the confidence factor goes up that the correct offset value for this particular two axis solar tracker mechanism as constructed and operating is being created and applied to the results of the Ephemeris calculation, which the combination aligns the CPV cells of this tracker mechanism at the proper angle to achieve the highest power from the inverter circuits of the tracker mechanism on each day and each hour of operation of the two axis tracker mechanism throughout the entire year, where the inverter circuits are the power output circuits of the two-axis tracker mechanism.

7. The hybrid solar tracking algorithm for a two-axis tracker mechanism of claim 1, where the offset values for all of the cells making at least a year's worth of entries in the matrix is created and maintained via the calibration procedure during the operation of the solar tracker mechanism, and each time a calibration occurs to determine the offset value for that particular cell, then the confidence level in the offset value grows, and the hybrid algorithm is configured to both 1) decrease the frequency of the calibration procedure occurring for that cell as well as 2) narrow down the range of search angles for the CPV cells deviating from a suggested starting angle used in the search algorithm to determine a highest power out of the two axis solar tracker, and thus, the algorithm takes into account how many times actual calibration procedures have occurred for this cell of the matrix to determine the confidence level in that offset value and consequently 1) how frequent calibrations occur and 2) the size of the range of deviation of search points from a starting angle that occurs in the calibration process for this cell.

8. The hybrid solar tracking algorithm for the two-axis solar tracker mechanism of claim 1, comprising:
where the hybrid solar tracking algorithm where the offset value is from the matrix to correct the angular coordinates for CPV cells contained in the two- axis solar tracker mechanism from those generated by the Ephemeris calculation alone in order to achieve the highest power out of the CPV cells, where the matrix is populated with data from periodic calibration measurements of the actual power being generated by a power output circuit of the two-axis solar tracker mechanism and applies the Kalman filtering to those measurements over time of the operation of the solar tracking mechanism to create an offset value from the matrix applied to results of the Ephemeris calculation to determine the angular coordinates for the CPV cells.

9. The hybrid solar tracking algorithm for the two-axis solar tracker mechanism of claim 1, comprising:
where the hybrid solar tracking algorithm uses both 1) a highly accurate solar tracking routine, including the Ephemeris calculation, with local GPS position data of the solar tracker mechanism to determine the angular coordinates that CPV cells contained in the solar tracker mechanism should be ideally positioned to relative to a current position of the Sun and 2) applies the Kalman filtering that is continuously updated with power measurements over the time of an operation the solar tracker mechanism to create the offset matrix to account for mechanical errors and other factors in order to combine the offset value with the determined angular coordinates from the solar tracker routine to achieve the maximum power out of a solar array over the entire day and throughout the year, and
where the highly accurate solar tracking routine uses an Ephemeris calculation with the local GPS position data of the solar tracker mechanism and the current time parameters to determine the angular coordinates that CPV cells contained in the solar tracker mechanism should be ideally positioned relative to the current position of the Sun.

10. The hybrid solar tracking algorithm for the two-axis tracker mechanism of claim 1, further comprising:
a set of magnetic reed sensors, one at each measured axis, used to determine 1) a reference position for the tilt linear actuators to control the tilt axis of the CPV cells as well as 2) a reference position for the slew drive motor to control the roll axis of the CPV cells, where one or more of the magnetic reed sensors are located and configured to allow a degree of rotation on the roll axis of the solar tracker to be accurately correlatable to a number of rotations of the slew drive motor,
where one or more of the magnetic reed sensors are located and configured to allow a position along each linear actuator to be accurately correlatable to a degree of rotation on the tilt axis of the solar tracker, and
where a first magnetic reed switch portion of a first magnetic reed sensor is located on an outer casing of a slew drive by a common roll axle coupled to the slew drive, and the magnetic portion of the magnetic reed sensor is affixed to a drive portion of the slew drive coupling to the common roll axle.

11. The hybrid solar tracking algorithm for the two-axis tracker mechanism of claim 10, further comprising:
where four or more paddles each contain a set of CPV cells and form a part of the two-axis solar tracker mechanism, and each paddle rotates on its own tilt axis,
where once the magnetic reed sensors create the reference position for the axes, then the degree of rotation of the CPV cells in the paddles on the roll axis is correlatable to a number of rotations of the slew drive motor, and the degree of rotation of the CPV cells in the first paddle on the tilt axis is also correlatable to an amount of movement in a first linear actuator, and
where a sensor position offset value parameter is created and stored in firmware to indicate a deviation from a physically measured level condition in that axis for the CPV cells, and what reading the magnetic reed sensors indicated at that time when the physically measured level condition was taken.

12. The hybrid solar tracking algorithm for a two-axis tracker mechanism of claim 1, where the highly accurate solar tracking routine determines the known location of the Sun in the sky in relation to CPV cells on this two axis tracker mechanism and receives time, date, and coordinate parameters from electronic circuits housed on the two axis tracker mechanism.

13. The hybrid solar tracking algorithm for the two-axis tracker mechanism of claim 3, where the measured actual power output from the AC generation inverter circuits may taken off the (I-V) curves and taken with a set of two or more calibration points is recorded into a cell of the offset matrix corresponding to that day of the year when the actual power output was measured, and the offset value stored in the cell is indicative of changes needed to the ideal angular positioning of the CPV cells resulting from the Ephemeris calculation.

14. The hybrid solar tracking algorithm for a two-axis tracker mechanism of claim 1, where the hybrid algorithm not only procedurally performs an initial calibration which provides data for that cell of the offset matrix, but then performs subsequent calibrations for that same cell periodically after that, where in addition, the hybrid two-axis solar tracking algorithm on the subsequent calibrations for that same cell both 1) decreases over time the frequency of the updates of data samples representative of the random variations for mechanical and other in accuracies and 2) decreases the offset range of search point positions that the solar tracker moves the CPV cells to when conducting the calibration process that measures actual power being generated by the power output circuit.

15. The hybrid solar tracking algorithm for a two-axis tracker mechanism of claim 1, where the hybrid solar tracking algorithm takes into account how many times actual calibration procedures have occurred for each cell of the matrix to determine the confidence level in that offset value for that cell and consequently 1) how frequent calibrations will occur and 2) the size of the range of deviation of search points from a starting angle that occurs in the calibration process for this cell.

16. The hybrid solar tracking algorithm for a two-axis tracker mechanism of claim 3, where the calibration measurement uses measured electrical power out of the inverter circuits of the solar tracker and then factors in measured direct normal incidence of solar radiation at that two axis tracker mechanism at the time the electrical power measurement is made, such as dividing the actual measured electrical power by the direct normal incidence at the time the measurement is made, to determine the highest power out of the solar tracker.

17. A method for solar tracking in a two-axis tracker mechanism in a concentrated photovoltaic system to control a movement of the two-axis solar tracker mechanism, comprising:
implementing a hybrid solar tracking algorithm that uses both 1) an Ephemeris calculation to supply the position of the Sun and 2) an offset value applied to results of the Ephemeris calculation to determine angular coordinates that the CPV cells contained in the two-axis solar tracker mechanism should be positioned at, in actuality, relative to a current position of the Sun to achieve a highest power output from a solar array containing the CPV cells, and
deriving the offset value from a periodic calibration measurement of actual power being generated by the CPV cells in the solar array of the two-axis tracker mechanism, where the data of the periodic calibration measurement is supplied to an offset matrix that uses Kalman filtering to evaluate those measurements over time of the operation of the solar tracking mechanism to create the offset value to be applied to the results of the Ephemeris calculation in order to determine the angular coordinates that the CPV cells contained in the two-axis solar tracker mechanism should be at in actuality to achieve the highest power output from the solar array; and
supplying the determined angular coordinates from the offset value being applied to the results of the Ephemeris calculation to a motion control circuit to cause the CPV cells to move to these determined angular coordinates.

18. The method for solar tracking of claim 17, further comprising: performing an initial calibration to provide data for each cell of the offset matrix, and then performing subsequent calibrations for that same cell periodically after that,
where the hybrid solar tracking algorithm on the subsequent calibrations for that same cell both 1) decreases over time the frequency of the updates of data samples representative of the random variations for mechanical and other in accuracies and 2) the offset range of calibration search point positions that the two axis solar tracker moves the CPV cells to when conducting the calibration process that measures actual power being generated by an AC inverter output circuit.

19. The method for solar tracking of claim 17, where the Ephemeris calculation uses local GPS position data of the solar tracker mechanism and the current time parameters to determine the angular coordinates that CPV cells contained in the solar tracker mechanism should be ideally positioned relative to the current position of the Sun and the hybrid solar tracking algorithm applies Kalman filtering to continuously update offset values over the time of an operation the solar tracker mechanism for the offset matrix to account for at least mechanical errors over the entire day and throughout the year,
using a set of magnetic reed sensors, one at each measured axis, used to determine 1) a reference position for each tilt linear actuators to control the tilt axis of the CPV cells as well as 2) a reference position for a slew drive motor to control the roll axis of the CPV cells, correlating a degree of rotation on the roll axis of the two axis solar tracker to a number of rotations of the slew drive motor; and
correlating a position along a linear actuator to be accurately correlatable to a degree of rotation on the tilt axis of the solar tracker.

20. An apparatus, comprising:
a hybrid solar tracking algorithm configured for a solar array of a two-axis solar tracker mechanism for a concentrated photovoltaic (CPV) system in order to control the movement of the solar array, where the hybrid solar tracking algorithm uses both 1) an Ephemeris calculation and 2) an offset value from a matrix to determine the angular coordinates for the CPV cells contained in the two-axis solar tracker mechanism to be moved to in order to achieve a highest power out of the CPV cells, where the matrix populates with data from periodic calibration measurements of actual power being generated by the solar tracker and the tracking algorithm applies Kalman filtering to those measurements over time of the operation of the solar tracking mechanism to create the offset value being applied to the Ephemeris calculation to determine the angular coordinates for the CPV cells, where hybrid solar tracking algorithm is implemented in software, hardware logic, and any combination of both and the portions implemented in software are stored in an executable manner on a non-transitory computer readable medium.
